(19) United States
(12) Patent Application Publication
(10) Pub. No.: US 2019/0131208 A1
(43) Pub. Date: May 2, 2019

(54) Multi-Layer Carrier System, Method for Producing a Multi-Layer Carrier System and Use of a Multi-Layer Carrier System

(71) Applicant: EPCOS AG, München (DE)

(72) Inventors: Thomas Feichtinger, Graz (AT); Franz Rinner, Deutschlandsberg (AT); Günter Pudmich, Köflach (AT); Werner Rollett, St Martin Im Sulmtal (AT); Michael Weilguni, Hagenberg (AT)

(73) Assignee: EPCOS AG, Munchen (DE)

(21) Appl. No.: 16/095,636

(22) PCT Filed: Feb. 16, 2017
(86) PCT No.: PCT/EP2017/053519

§ 371 Date: Oct. 22, 2018

(30) Foreign Application Priority Data
Apr. 22, 2016 (DE) 10 2016 107 495.0

(51) Int. Cl. H01L 23/373; H01L 23/498; H05K 1/03; H01L 33/62; F21S 41/141; B60Q 1/04

(52) U.S. Cl. CPC H01L 23/3735; H01L 23/3736; H01L 23/49822; H05K 1/0306; B60Q 1/04; H01L 23/49833; H01L 33/62; F21S 41/141; H01L 23/3731

(57) ABSTRACT

A multi-layer carrier system and a method for producing a multi-layer carrier system are disclosed. In an embodiment a multi-layer carrier system includes at least one multi-layer ceramic substrate and at least one matrix module of heat-producing semiconductor components, wherein the semiconductor components are arranged on the multi-layer ceramic substrate, and wherein the matrix module is electrically conductively connected to a driver circuit by way of the multi-layer ceramic substrate.

This patent application is a national phase filing under section 371 of PCT/EP2017/053519, filed Feb. 16, 2017, which claims the priority of German patent application 10 2016 107 495.0, filed Apr. 22, 2016, each of which is incorporated herein by reference in its entirety.

### TECHNICAL FIELD

The present invention relates to a multi-layer carrier system, for example, a carrier system for a power module having a matrix of heat sources. The present invention furthermore relates to a method for producing a multi-layer carrier system and to the use of a multi-layer carrier system.

### BACKGROUND

Carrier systems, for example, for light modules generally comprise a printed circuit board or a metal-core circuit board. Corresponding carrier systems are known, for example, from the documents U.S. Publication No. 2009/0129079 A1 and U.S. Publication No. 2008/0151547 A1.

One known light matrix concept consists of a plurality of LED array modules on an IMS (insulated metal substrate) consisting of a 1 mm to 3 mm thick metal layer and an insulation layer and wiring on a layer at the surface, which are in each case screwed on a heat sink and can be switched on and off by way of a control unit. A complicated optical unit is required for each LED array module, which makes the system complex and expensive.

### SUMMARY OF THE INVENTION

Embodiments provide an improved carrier system, a method for producing an improved carrier system and the use of an improved carrier system.

In accordance with one aspect, a multi-layer carrier system, carrier system for short, is specified. The carrier system comprises at least one multi-layer ceramic substrate. The multi-layer ceramic substrate is a functional ceramic. The carrier system comprises at least one matrix module of heat-producing semiconductor components. The heat-producing semiconductor components comprise, for example, light sources, for example, LEDs. The matrix module comprises heat sources arranged in matrix form. Preferably, the at least one matrix module comprises an LED matrix module.

The matrix module preferably comprises a multiplicity of individual elements/semiconductor components. The individual elements themselves can in turn comprise a multiplicity of subcomponents. The matrix module can comprise, for example, a multiplicity of individual LEDs as semiconductor components. As an alternative thereto, the matrix module can comprise a multiplicity of LED arrays as semiconductor components. The matrix module can also comprise a combination of individual LEDs and LED arrays. The matrix module can comprise a plurality of light modules, for example, two, three, four, five or ten light modules. The respective light module preferably comprises m×n heat-producing semiconductor components, wherein preferably m≥2 and n≥2. By way of example, the matrix module comprises a 4×8×8 light matrix module.

The semiconductor components are arranged on the multi-layer ceramic substrate. The semiconductor components are connected to form the matrix module by the multi-layer ceramic substrate. The semiconductor components are secured on a top side of the multi-layer ceramic substrate, for example, by way of a thermally conductive material, for example, a solder paste or a silver sintering paste (Ag sintering paste). The matrix module or the semiconductor components is/are thermally and electrically linked to the multi-layer ceramic substrate by way of the thermally conductive material. The multi-layer ceramic substrate serves for mechanical stabilization and for contacting of the matrix module, in particular of the heat-producing semiconductor components of the matrix module.

The matrix module is electrically conductively connected to a driver circuit by way of the multi-layer ceramic substrate. The driver circuit serves for driving the semiconductor components.

The carrier system can comprise, for example, two, three or more matrix modules. In this case, each matrix module can be arranged on a separate multi-layer ceramic substrate. Alternatively, a plurality of matrix modules can also be arranged on a common multi-layer ceramic substrate.

The construction of the carrier system by way of the multi-layer ceramic substrate may allow a very compact embodiment and the integration of electronic components directly into the ceramic. Thus, a compact and highly adaptive carrier system can be made available.

In accordance with one exemplary embodiment, the multi-layer carrier system is configured to individually drive the semiconductor components of the matrix module. Preferably, the multi-layer ceramic substrate comprises an integrated multi-layer individual wiring for individually driving the semiconductor components. In this context, the term “integrated” means that the multi-layer individual wiring is formed in an inner region of the multi-layer ceramic substrate. The multi-layer ceramic construction enables the individual driving of the semiconductor components in a very confined space. A very compact carrier system is thus made available.

In accordance with one exemplary embodiment, the multi-layer ceramic substrate comprises a varistor ceramic. By way of example, the multi-layer ceramic substrate predominantly comprises ZnO. The multi-layer ceramic substrate can further comprise bismuth, antimony, praseodymium, yttrium and/or calcium, and/or further dopings. The multi-layer ceramic substrate can comprise strontium titanate (SrTiO₃) or silicon carbide (SiC). By virtue of the varistor ceramic, overvoltage protection can be integrated into the carrier system. In this case, compact dimensions are combined with optimum protection for electronic structures.

In accordance with one exemplary embodiment, the multi-layer ceramic substrate comprises a multiplicity of internal electrodes and vias. The internal electrodes are arranged between varistor layers of the multi-layer ceramic substrate. The internal electrodes comprise Ag and/or Pd. Preferably, the internal electrodes consist 100% of Ag. The internal electrodes are electrically conductively connected to the vias. Preferably, the multi-layer ceramic substrate comprises at least one integrated ESD structure for protection against overvoltages. All components are arranged in a space-saving manner in the inner region of the multi-layer ceramic substrate. The individual driving of the semiconductor components in a very confined space is thus made possible. Besides the integration of the overvoltage protective function, the varistor ceramic also allows the integration of a temperature sensor or thermal protection. A very adaptive and long-lived carrier system is thus made available.

In accordance with one exemplary embodiment, the multi-layer ceramic substrate has a thermal conductivity of greater than or equal to 22 W/mK. The thermal conductivity is significantly higher than the thermal conductivity of known carrier substrates, such as an IMS substrate, for example, which has a thermal conductivity of 5-8 W/mK. The heat generated by the matrix module can thus be optimally dissipated.

In accordance with one exemplary embodiment, the driver circuit preferably has an overtemperature protective function and/or an overcurrent and/or overvoltage protective function. The driver circuit can comprise, for example, an NTC (negative temperature coefficient) thermistor for protection against excessively high temperatures. Alternatively or additionally, the driver circuit can comprise a PCT (positive temperature coefficient) thermistor for protection against overcurrent.

In accordance with one exemplary embodiment, the carrier system comprises a further substrate. Preferably, the further substrate is formed in insulating or semiconducting fashion. Preferably, the further substrate has an inert surface. In this context, “inert” is understood to mean that a surface of the further substrate has a high insulation resistance. The high insulation resistance protects the surface of the substrate against external influences. The high insulation resistance makes the surface insensitive, for example, to electrochemical processes, such as the deposition of metallic layers on the surface. The high insulation resistance furthermore makes the surface of the substrate insensitive to aggressive media, e.g., aggressive fluxes used in soldering processes, for example.

The substrate can comprise a ceramic substrate. In particular, the substrate can comprise AlN or AlOₓ, for example, Al₂O₃. However, the substrate can also comprise silicon carbide (SiC) or boron nitride (BN). The substrate can comprise a further multi-layer ceramic substrate. This is advantageous in particular because a multiplicity of internal structures (conductor tracks, ESD structures, vias) can be integrated in a multi-layer ceramic substrate. The further substrate can comprise a varistor ceramic, for example. As an alternative thereto, the substrate can be configured as an IMS substrate. As an alternative thereto, the substrate can comprise a metal-core printed circuit board (metal-core PCP).

The substrate serves for mechanical and thermomechanical stabilization of the carrier system. The substrate furthermore serves as a further redistribution wiring plane for the individual driving of the semiconductor components.

The multi-layer ceramic substrate is arranged on the further substrate, in particular at a top side of the substrate. By way of example, a thermally conductive material, for example, a solder paste or an Ag sintering paste, can be formed between the multi-layer ceramic substrate and the further substrate. The thermally conductive material serves for the thermal and electrically conductive connection of substrate and multi-layer ceramic substrate. As an alternative thereto, the further substrate can also be thermally and electrically linked to the multi-layer ceramic substrate by way of a combination of a thermally conductive paste and a solder paste or Ag sintering paste. By way of example, BGA (ball grid array) contacts can be configured in the shape of a rim in an edge region of the multi-layer ceramic substrate. Thermally conductive paste can furthermore be formed in a further region, e.g., in an inner region or central region of the underside of the multi-layer ceramic substrate, between the multi-layer ceramic substrate and the further substrate. The thermally conductive paste has insulating properties. In particular, the thermally conductive paste serves only for thermal linking.

In this exemplary embodiment, the driver circuit is constructed directly on a surface of the substrate, for example, the top side of the substrate. The driver circuit is preferably directly connected to conductor tracks on the surface of the substrate. The conductor tracks are directly connected to the individual interconnection integrated in the multi-layer ceramic substrate.

In accordance with one exemplary embodiment, the carrier system comprises a printed circuit board. The printed circuit board at least partly surrounds the substrate. The substrate is preferably arranged in a cutout of the printed circuit board. The cutout preferably completely penetrates through the printed circuit board. The driver circuit is constructed directly on a surface of the printed circuit board. The driver circuit is preferably directly connected to conductor tracks on the surface of the printed circuit board. The conductor tracks on the printed circuit board are either directly connected to the individual interconnection integrated in the multi-layer ceramic substrate or they are connected to conductor tracks on the substrate, for example, by way of a plug contact.

In accordance with one exemplary embodiment, the carrier system comprises a heat sink. The heat sink serves for dissipating heat from the carrier system. The heat sink can be thermally linked to the further substrate. As an alternative thereto, the heat sink can also be thermally linked to the multi-layer ceramic substrate.

By way of example, a thermally conductive material, preferably a thermally conductive paste, is formed between the heat sink and the substrate and/or between the heat sink and the multi-layer ceramic substrate. The thermally conductive paste serves for the electrical insulation of heat sink and further substrate/multi-layer ceramic substrate. By means of the thermally conductive paste, the heat generated by the semiconductor components is effectively conducted to the heat sink and dissipated from the system by said heat sink. The thermally conductive paste is furthermore configured and arranged to buffer thermal stresses between the multi-layer ceramic substrate/the further substrate and the heat sink, said thermal stresses being produced, for example, by the temperature change when the semiconductor components are switched on.

The heat sink can comprise aluminum casting material, for example. A corresponding heat sink has a high coefficient of thermal expansion. By way of example, the coefficient of expansion of the heat sink is 18 to 23 ppm/K. The coefficient of expansion of the multi-layer ceramic substrate is in the region of 6 ppm/K. The coefficient of expansion of the further substrate is in the range of 4 to 9 ppm/K, for example, 6 ppm/K. The coefficients of expansion of multi-layer ceramic substrate and further substrate are preferably well matched to one another. Thermal stresses can occur between the multi-layer ceramic substrate and the further substrate in the event of temperature changes (for example, during soldering processes or during the driving of the semiconductor components). The corresponding stresses can be well compensated for by the optimum coordination of multi-layer ceramic substrate and further substrate. By means of the thermally conductive paste between heat sink and multi-layer ceramic substrate and/or further substrate, it is possible to compensate for the thermal differences and the attendant thermal expansions between the multi-layer ceramic substrate and/or the further substrate and the heat sink. A carrier system having a particularly long lifetime is thus made available.

In an alternative exemplary embodiment, however, the heat sink can also comprise aluminum-silicon carbide. The heat sink can comprise a copper-tungsten alloy or a copper-molybdenum alloy. The heat sink can comprise in particular molybdenum built up on copper. Aluminum-silicon carbide, copper-tungsten and copper-molybdenum have the advantage that these materials have a coefficient of thermal expansion similar to that of the multi-layer ceramic substrate and/or the further substrate. By way of example, a corresponding heat sink has a coefficient of thermal expansion of approximately 7 ppm/K. It is thus possible to reduce or avoid thermal stresses between multi-layer ceramic substrate/further substrate and heat sink. In this case, therefore, the use of the thermally conductive paste can also be obviated or a layer thickness of the thermally conductive paste can turn out to be smaller than in the exemplary embodiment with the heat sink composed of aluminum casting material.

In accordance with a further aspect, a method for producing a multi-layer carrier system is described. Preferably, the carrier system described above is produced by the method. All features that have been described in association with the carrier system also find application for the method, and vice versa. In this case, the method steps described below can also be carried out in an order deviating from the description.

A first step involves producing a multi-layer ceramic substrate having integrated conductor tracks, at least one ESD structure and vias. The multi-layer ceramic substrate preferably comprises a varistor. In order to produce the multi-layer ceramic substrate, ceramic green sheets are provided, wherein the green sheets are printed with electrode structures for forming the conductor tracks. The green sheets are provided with cutouts for forming the vias. Furthermore, the ESD structure is introduced into the green stack. The green stack is subsequently pressed and sintered.

A further—optional—step involves providing a substrate. The substrate can comprise a ceramic substrate. The substrate can comprise a metallic substrate. Preferably, conductor tracks are formed at a surface of the substrate. The multi-layer ceramic substrate is arranged on the substrate. Preferably, a thermally conductive material, for example, a solder paste or an Ag sintering paste, is arranged at the top side of the substrate beforehand.

A further step involves arranging at least one matrix module of heat-producing semiconductor components at a top side of the multi-layer ceramic substrate. Preferably, a thermally conductive material, for example, a solder paste or an Ag sintering paste, is arranged at the top side of the multi-layer ceramic substrate beforehand. The semiconductor elements are connected to form the matrix module by way of the multi-layer ceramic substrate.

A further step involves sintering the matrix module with the multi-layer ceramic substrate, for example, by means of Ag sintering, for example, μAg sintering.

An optional further step involves providing a printed circuit board. The printed circuit board has a cutout completely penetrating through the printed circuit board. The substrate is at least partly introduced into the cutout. In other words, the printed circuit board is arranged around the substrate. The printed circuit board is electrically conductively connected to the substrate, for example, by way of a plug contact or a bond wire.

A further step involves making driver components available. In one exemplary embodiment, the driver components are arranged on the substrate, in particular a surface of the substrate, for the purpose of driving the semiconductor components by way of the conductor tracks and vias of the multi-layer ceramic substrate. As an alternative thereto, the driver components can also be realized on a surface of the multi-layer ceramic substrate. In this case, providing the substrate can also be omitted. As an alternative thereto, in the exemplary embodiment with the printed circuit board, the driver components are formed on the printed circuit board, in particular a surface of the printed circuit board.

A further step involves thermally connecting the substrate to a heat sink. As an alternative thereto, the multi-layer ceramic substrate is thermally connected to the heat sink. In this case, providing the substrate is omitted. By way of example, in a preceding step, thermally conductive material is arranged at an underside of the substrate and/or of the multi-layer ceramic substrate. The thermally conductive material preferably comprises an electrically insulating thermally conductive paste. However, arranging the thermally conductive material can also be obviated given a corresponding configuration of the heat sink (aluminum-silicon carbide, copper-tungsten or copper-molybdenum heat sink).

The carrier system comprises at least one matrix light module with punctiform individual driving of a large number of LEDs. The surroundings can thus be illuminated or masked out in a highly differentiated manner. The construction by way of a multi-layer varistor having high thermal conductivity allows a very compact embodiment, the integration of ESD protective components and the construction of the driver circuit directly on the ceramic. A compact and highly adaptive carrier system is thus provided.

In accordance with a further aspect, a use of a multi-layer carrier system is described. All features that have been described in association with the carrier system and the method for producing the carrier system also find application for the use, and vice versa.

The use of a multi-layer carrier system, in particular of the multi-layer carrier system described above, is described. The carrier system is used, for example, in a matrix LED headlight in the automotive field. The carrier system can also be used in the medical field, for example, with the use of UV LEDs. The carrier system can be used for applications in power electronics. The carrier system described above is highly adaptive and can thus find application in a wide variety of systems.

In accordance with a further aspect, the use of a multi-layer ceramic substrate is described. The multi-layer ceramic substrate preferably corresponds to the multi-layer ceramic substrate described above. The multi-layer ceramic substrate preferably comprises a varistor ceramic. The multi-layer ceramic substrate preferably comprises an integrated multi-layer individual wiring for the individual driving of heat-producing semiconductor components. The multi-layer ceramic substrate is preferably used in the carrier system described above.

### BRIEF DESCRIPTION OF THE DRAWINGS

The drawings described below should not be interpreted as true to scale. Rather, individual dimensions may be illustrated as enlarged, reduced or even distorted, for the sake of better illustration.

Elements which are identical to one another or which perform the same function are designated by identical reference signs.

In the figures:

FIG. 1 shows a plan view of a multi-layer carrier system in accordance with one exemplary embodiment;

FIG. 1a shows a plan view of a heat-producing semiconductor component;

FIG. 1b shows a plan view of the heat-producing semiconductor component in accordance with FIG. 1b;

FIG. 1c shows a plan view of a heat-producing semiconductor component in accordance with a further exemplary embodiment;

FIG. 2 shows a sectional illustration of a multi-layer carrier system in accordance with one exemplary embodiment;

FIG. 3 shows a sectional illustration of a multi-layer carrier system in accordance with the exemplary embodiment from FIG. 1;

FIG. 4 shows a sectional illustration of a multi-layer carrier system in accordance with one exemplary embodiment;

FIG. 5 shows the illustration of an internal wiring for the multi-layer carrier system in accordance with FIG. 4;

FIG. 6 shows the illustration of an internal wiring for the multi-layer carrier system in accordance with FIG. 3;

FIG. 7 shows one exemplary embodiment of an internal wiring of a multi-layer carrier system;

FIG. 8 shows a sectional illustration of a multi-layer carrier system in accordance with a further exemplary embodiment;

FIG. 9 shows a sectional illustration of a multi-layer carrier system in accordance with a further exemplary embodiment; and

FIG. 10 shows one exemplary embodiment of a driver concept for a multi-layer carrier system.

### DETAILED DESCRIPTION OF ILLUSTRATIVE EMBODIMENTS

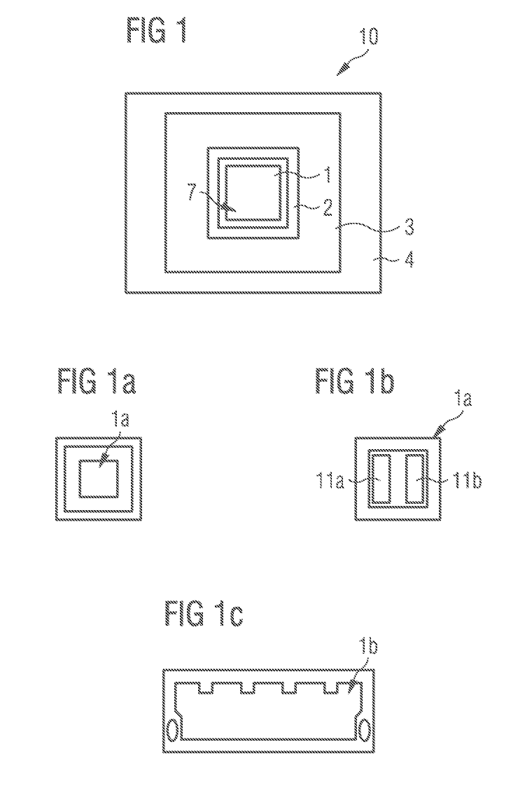

FIGS. 1 and 3 show a plan view and a sectional view of a multi-layer carrier system 10 in accordance with a first exemplary embodiment. The multi-layer carrier system 10, carrier system 10 for short, comprises a heat source 1. However, the carrier system 10 can also comprise a plurality of heat sources 1, for example, two, three or more heat sources 1. The respective heat source 1 preferably comprises a multiplicity of heat-producing semiconductor components 1a, 1b.

The heat source 1 can comprise two, three, 10 or more, preferably a multiplicity of, individual LEDs 1a. FIG. 1a shows a plan view of a top side of an individual LED 1a. FIG. 1b shows a plan view of the underside of the individual LED is with p-type connection region 11a and n-type connection region 11b.

However, the heat source 1 can also comprise an LED array 1b or a plurality of LED arrays 1b (see FIG. 1c). Preferably, the heat source 1 is configured as an LED matrix module 7 having a multiplicity of LEDs 1a and/or LED arrays 1b. By way of example, the heat source 1 comprises a 4×8×8 LED matrix module having a total of 256 LEDs. Preferably, the carrier system 10 is a multi-LED carrier system.

The carrier system 10 comprises a multi-layer ceramic substrate 2. The multi-layer ceramic substrate 2 serves as a carrier substrate for the heat source 1. The multi-layer ceramic substrate 2 is configured to effectively dissipate the heat generated by the heat source 1. The multi-layer ceramic substrate 2 is furthermore configured to electrically contact the heat source 1 and in particular the individual LEDs, as will be described in detail later.

The heat source 1 is arranged on the multi-layer ceramic substrate 2, in particular a top side of the multi-layer ceramic substrate 2. By way of example, a thermally conductive material 6a (FIG. 3), preferably a solder paste or an Ag sintering paste, is formed between the heat source 1 and the top side of the multi-layer ceramic substrate 2. The thermally conductive material 6a comprises a material having a high thermal conductivity. The thermally conductive material 6a furthermore serves for electrically contacting the multi-layer ceramic substrate 2.

The multi-layer ceramic substrate 2 likewise has a high thermal conductivity. By way of example, the thermal conductivity of the multi-layer ceramic substrate 2 is 22 W/mK. By virtue of the high thermal conductivity of thermally conductive material 6a and multi-layer ceramic substrate 2, the heat generated by the heat source 1 can be effectively forwarded and dissipated—, for example, by way of a heat sink 4—from the carrier system 10.

The multi-layer ceramic substrate 2 is preferably a multi-layer varistor. A varistor is a nonlinear component whose resistance decreases greatly when a specific applied voltage is exceeded. A varistor is therefore suitable for harmlessly dissipating overvoltage pulses. The multi-layer ceramic substrate 2 and in particular the varistor layers (not explicitly illustrated) preferably comprise zinc oxide (ZnO), in particular polycrystalline zinc oxide. Preferably, the varistor layers consist of ZnO at least to the extent of 90%. The material of the varistor layers can be doped with bismuth, praseodymium, yttrium, calcium and/or antimony or further additives or dopants. As an alternative thereto, however, the varistor layers can, for example, also comprise silicon carbide or strontium titanate.

The multi-layer ceramic substrate 2 has a thickness or vertical extent of 200 to 500 μm. Preferably, the multi-layer ceramic substrate 2 has a thickness of 300 μm or 400 μm. Preferably, a metallization is formed (not explicitly illustrated) at a top side and an underside of the multi-layer ceramic substrate 2. The respective metallization has a thickness of 1 μm to 15 μm, for example, 3 μm to 4 μm. A large thickness of the metallization has the advantage that heat generated by the LEDs 1a/LED arrays 1b of the heat source 1 can also be emitted to the surroundings by way of the surface of the multi-layer ceramic substrate 2 (lateral heat convection) since the thermal conductivity is improved at the surface.

In this exemplary embodiment, the carrier system 10 comprises a further, for example, ceramic, substrate 3. The substrate 3 serves for improving the mechanical and thermomechanical robustness of the carrier system 10. The substrate 3 can comprise, for example, AlN or Al₂O₃ (ceramic substrate). The substrate 3 can comprise a further multi-layer ceramic substrate, in particular a further varistor ceramic comprising a different material. As an alternative thereto, however, an IMS (insulated metal substrate) or a metal-core printed circuit board can also find application as substrate. An IMS is, for example, an insulated metal substrate comprising aluminum or copper. An insulating ceramic or an insulating polymer layer having copper lines for redistribution wiring for the driving of the individual LEDs is formed at a surface of the IMS. The substrate 3 has a thickness or vertical extent of 300 μm to 1 mm, for example, 500 μm.

Besides the heat conduction and a redistribution wiring for the LEDs, the substrate 3 also has the purpose of compensating for the different coefficients of expansion of the heat sink 4 and of the multi-layer ceramic substrate 2. A stable and long-lived carrier system 10 is thus realized.

The substrate 3 is arranged at an underside of the multi-layer ceramic substrate 2. By way of example, the substrate 3 is connected to the multi-layer ceramic substrate 2 by way of an—as described above—thermally conductive material 6a, for example, a solder paste or an Ag sintering paste. The thermally conductive material 6a has a thickness or vertical extent of between 10 μm and 500 μm, for example, 300 μm.

The substrate 3, in particular an underside of the substrate 3, is connected to the abovementioned heat sink 4, which serves to dissipate the heat generated by the heat source 1 from the system. By way of example, the substrate 3 is adhesively bonded or screwed to the heat sink 4.

Preferably, thermally conductive material 6b, in particular an electrically insulating thermally conductive paste, is arranged between the substrate 3 and the heat sink 4. As an alternative thereto, however, a use of the thermally conductive material 6b can also be obviated or turn out to be smaller (not explicitly illustrated) if the heat sink 4 has a coefficient of thermal expansion similar to that of the substrate 3 (heat sink 4 comprising aluminum-silicon carbide, copper-tungsten or copper-molybdenum). Preferably, the heat sink 4 in this case comprises molybdenum built up on copper.

The heat sink 4 has cooling ribs 4a. In order to achieve a good convection, the cooling ribs 4a have to be greatly ventilated. Alternatively or additionally, a cooling of the carrier system 10 can also be achieved by means of water cooling.

For driving the heat source 1 and in particular the individual LEDs 1a, 1b, the carrier system 10 has an internal wiring or redistribution wiring. In particular, the multi-layer ceramic substrate 2 has an integrated individual wiring/wiring for the LEDs of the heat source 1, said wiring being situated within the multi-layer ceramic substrate 2. In other words, the LEDs can be individually driven by way of or with the aid of the multi-layer ceramic substrate 2.

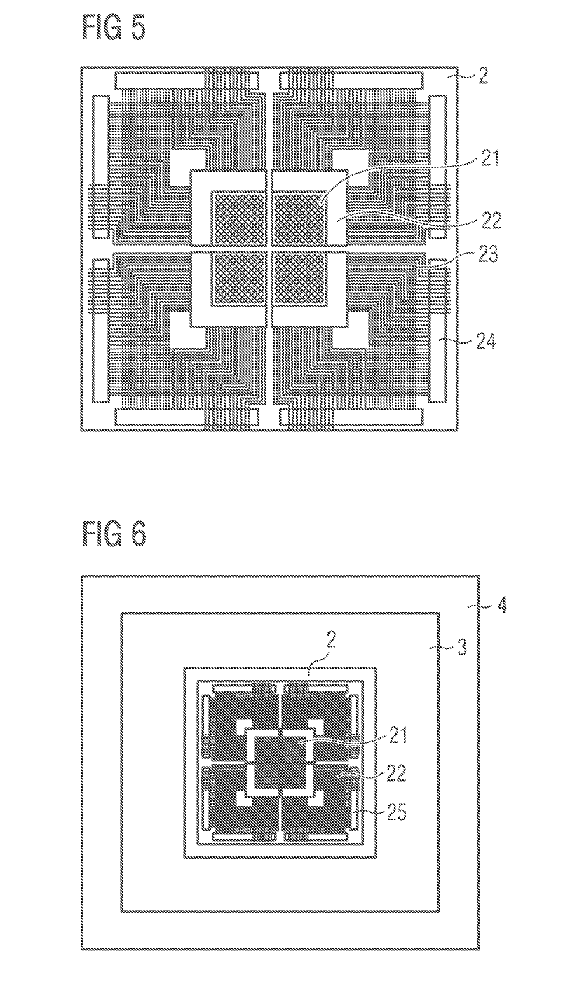

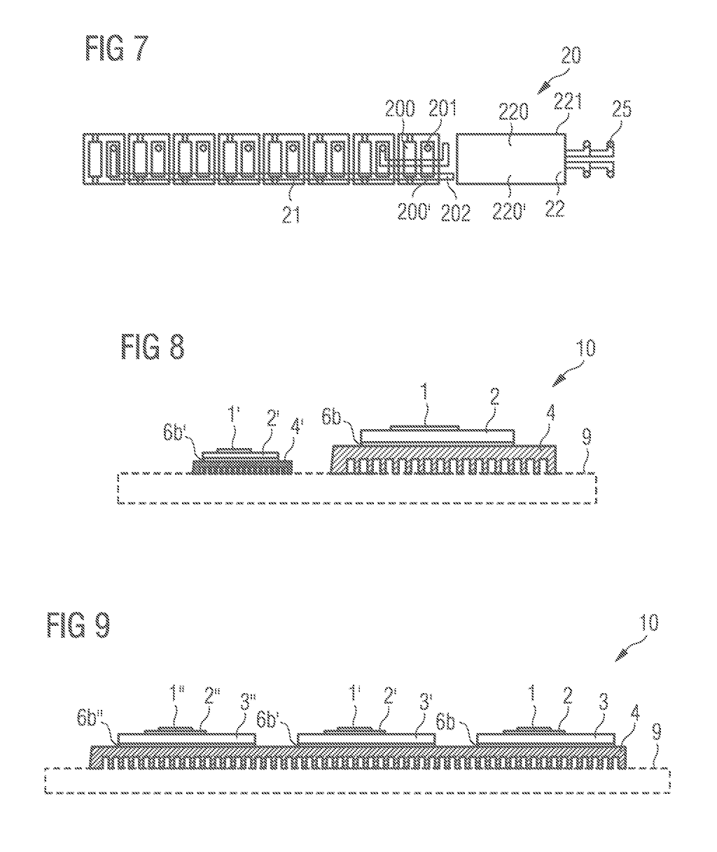

One example of an internal wiring for a multi-layer component 10 in accordance with FIGS. 1 and 3 is illustrated here in FIGS. 6 and 7. In FIG. 7, the internal wiring of a series of eight LEDs is implemented with interconnection by way of four planes for individual driving and five ground planes. The illustration shows a half-row for eight modules. The multi-layer ceramic substrate 2 comprises a plurality of internal electrodes 202 (FIG. 7) formed between the varistor layers. The internal electrodes 202 are arranged one above another within the multi-layer ceramic substrate 2. The internal electrodes 202 are furthermore expediently electrically isolated from one another. Preferably, the internal electrodes 202 are furthermore arranged one above another and configured in such a way that they at least partly overlap.

The multi-layer ceramic substrate 2 comprises at least one via 8, 201 (FIGS. 3 and 7), preferably a plurality of vias 8, 201. In this case, a via 8, 201 comprises a cutout in the multi-layer ceramic substrate 2, which cutout is filled with an electrically conductive material, in particular a metal. The vias 8, 201 serve to electrically connect the LEDs to a driver circuit, as will be described in detail later. The vias 8, 201 are electrically conductively connected to the internal electrodes 202.

The multi-layer ceramic substrate 2, for the individual driving of the LEDs, furthermore comprises a contact region 21 for producing an electrically conductive contact with the heat source 1. The contact region 21 is formed in a central region of the multi-layer ceramic substrate 2 (FIG. 6). In this exemplary embodiment, the contact region 21 is divided into four partial regions (FIG. 6) for contacting an individual module of in each case 8×8 LEDs. Overall, therefore, a very large number of, for example, 256 (4×8×8) LEDs are intended to be driven by way of the internal wiring. The contact region 21 is provided with top contacts or connection pads 200 for the LEDs (FIG. 7), which are electrically conductively connected to the internal electrodes 202.

The multi-layer ceramic substrate 2 furthermore comprises a contact 25 in order to produce an electrically conductive connection to the substrate 3. The contact 25 is preferably formed in an edge region of the multi-layer ceramic substrate 2 (FIG. 6). The contact 25 is preferably a BGA contact (solder balls) or is realized by means of wire bonds. Besides the electrical linking, the contact 25 also serves as a stress buffer by compensating for thermomechanical differences between substrate 3 and multi-layer substrate 2.

The multi-layer ceramic substrate 2 furthermore comprises an integrated ESD (electrostatic discharge) structure 22. The ESD structure 22 has an ESD electrode surface 220, 220′ and a ground electrode 221. Like the internal electrodes 202 and the vias 8, 201, the ESD structure 22 is also integrated into the substrate 2 during the production of the multi-layer ceramic substrate 2. The heat source 1, which is very sensitive to overvoltages such as can be triggered, e.g., by an ESD pulse, is protected against these current or voltage surges with the aid of the ESD structure 22. The ESD structure 22 is realized in the shape of a frame around the central contact region 21 (FIG. 6). Furthermore, the contact 25 is realized in the shape of a frame around the ESD structure 22 (FIG. 6).

The multi-layer ceramic substrate 2 can furthermore have an integrated temperature sensor or an overtemperature protective function (not explicitly illustrated).

By virtue of the multi-layer construction of the multi-layer ceramic substrate 2, the individual driving of the LEDs is realized in a very confined space. In this case, as described above, the varistor ceramic also allows the integration of an overvoltage protective function (ESD, surge pulses) and of an overtemperature protective function. A compact and highly adaptive carrier system 10 that satisfies a wide variety of requirements can thus be achieved.

For driving the heat source 1 and in particular the LEDs, the carrier system 10 finally comprises a driver circuit (not explicitly illustrated). The driver circuit can have implemented protection functions. The driver circuit preferably has an overtemperature protection (for example, by way of an NTC thermistor) and/or an overvoltage or overcurrent protection (for example, by way of a PTC thermistor).

In this exemplary embodiment, the driver circuit is realized on the substrate 3, in particular on a surface of the substrate 3. Preferably, the driver circuit is realized by means of reflow soldering at the top side of the substrate 3. The driver circuit is connected to metallic conductor tracks, for example, copper lines, at the surface of the substrate 3. In this exemplary embodiment, the substrate 3 thus serves as driver substrate. The substrate 3 serves in particular as further redistribution wiring plane in order to drive the LEDs individually by way of the driver circuit. The conductor tracks at the surface of the substrate 3 are electrically conductively connected to the wiring integrated in the multi-layer ceramic substrate 2 in order to individually drive the LEDs.

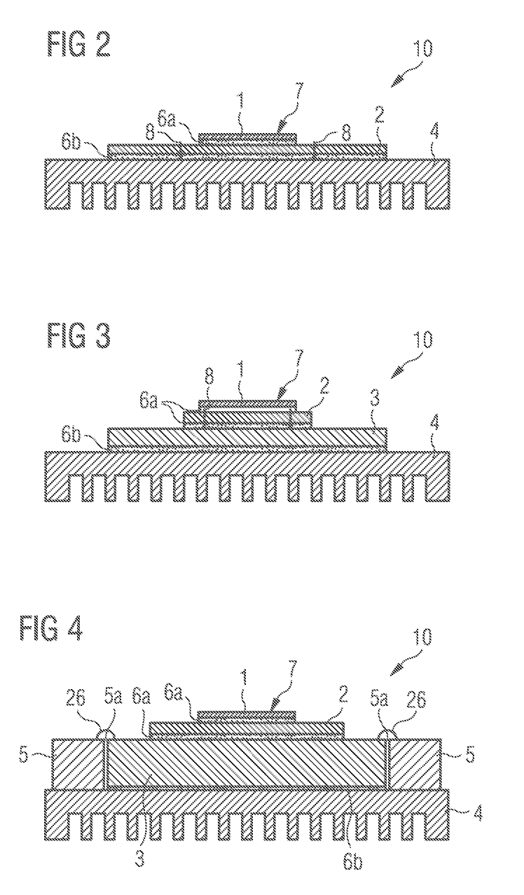

FIG. 2 shows a sectional illustration of a multi-layer carrier system 10 in accordance with a further exemplary embodiment. In contrast to the multi-layer carrier system in accordance with FIGS. 1 and 3, the carrier system 10 from FIG. 2 does not comprise a further substrate 3. Rather, the multi-layer ceramic substrate 2 in this exemplary embodiment is directly connected to the heat sink 4. Thermally conductive material 6b (electrically insulating thermally conductive paste) can be arranged between the multi-layer ceramic substrate 2 and the heat sink 4.

In this exemplary embodiment, the driver circuit is realized directly on a surface of the multi-layer ceramic substrate 2, for example, the underside thereof. The construction of the multi-layer carrier system 10 can be simplified by the omission of the substrate 3 (driver substrate). In particular, all electronic building blocks required for the individual driving of the LEDs, such as the redistribution wiring and the driver circuit, are realized in and/or on the multi-layer ceramic substrate 2.

All further features of the multi-layer ceramic substrate 10 in accordance with FIG. 2, in particular the construction and the composition of the multi-layer ceramic substrate 2 and also the internal wiring (see FIG. 7), correspond to the features described in association with FIGS. 1 and 3.

FIG. 4 shows a sectional illustration of a multi-layer carrier system 10 in accordance with a further exemplary embodiment. Only the differences with respect to the carrier system in accordance with FIGS. 1 and 3 are described below.

In contrast to the multi-layer carrier system in accordance with FIGS. 1 and 3, the carrier system 10 additionally comprises a printed circuit board 5. The printed circuit board 5 surrounds the substrate 3. Preferably, the substrate 3 is completely surrounded by the printed circuit board 5 at least at its end sides.

For this purpose, the printed circuit board 5 has a cutout 5a, in which the substrate 3 is arranged. The cutout 5a completely penetrates through the printed circuit board 5. The printed circuit board 5 is electrically conductively connected to the substrate 3 by means of a plug connection 26 or a bond wire 26. As described in association with FIGS. 1 and 3, the substrate 3 is thermally connected. By way of example, thermally conductive material 6b (electrically insulating thermally conductive paste) is arranged between the substrate 3 and the heat sink 4.

In this exemplary embodiment, the driver circuit is realized directly on a surface of the printed circuit board 5, for example, the top side thereof (not explicitly illustrated). Besides the multi-layer ceramic substrate 2, the substrate 3 serves as a further redistribution wiring plane in order to drive the LEDs individually by way of the driver circuit. In particular, the driver circuit can be connected to electrical lines at the surface of the substrate 3. However, the substrate 3 in this exemplary embodiment does not constitute a driver substrate, since the driver circuit is arranged on the printed circuit board 5 and not on the substrate 3.

FIG. 5 shows one example of an internal wiring for a multi-layer component 10 in accordance with FIG. 4. In this case, the illustration shows the internal wiring of a 4×8×8 light matrix module with individual driving of 256 LEDs and integrated ESD protection at the input of a plug contact and at the input to the LED module.

In this case, the multi-layer ceramic substrate 2 comprises the contact region 21 for producing an electrically conductive contact with the LED matrix. The contact region 21 is divided into four central partial regions for contacting an individual module of in each case 8×8 LEDs.

The ESD structure 22 is situated in a manner arranged in the shape of a frame around the contact region 21. An electrically conductive connection to the driver circuit on the printed circuit board 5 is produced by way of a physical plug contact 24 in an outer edge region of the multi-layer ceramic substrate 2. The redistribution wiring 23 for the individual contacting of the LEDs is formed between the plug contact 24 and the ESD structure 22 (in this respect, see also FIG. 7). The ESD structure 22 is formed at the input of the plug contact 24 and also at the input to the contact region 21.

All further features of the multi-layer ceramic substrate 10 in accordance with FIG. 4 correspond to the features described in association with FIGS. 1 and 3. This concerns in particular the structure and the connection of the heat source 1, the multi-layer ceramic substrate 2 and also the substrate 3 and also the detailed configuration of individual wiring/redistribution wiring and driver circuit.

FIG. 8 shows a sectional illustration of a multi-layer carrier system 10 in accordance with a further exemplary embodiment. The carrier system 10 comprises a plurality of heat sources 1, 1′. In particular, FIG. 8 shows two heat sources 1, 1′, but a larger number of heat sources, for example, 3, 4 or 5 heat sources, can also be provided.

The respective heat source 1, 1′ comprises an LED matrix module, wherein the respective module comprises a different number of LEDs. By way of example, the heat source 1′ comprises a smaller number of LEDs (individual LEDs 1a and/or LED arrays 1b), for example, half of the LEDs, by comparison with the heat source 1. The heat source 1′ thus produces less heat than the heat source 1.

As already described in association with the carrier system 10 from FIG. 2, the basic construction of which corresponds to that of the carrier system 10 from FIG. 8, the respective heat source 1, 1′ is arranged on a multi-layer ceramic substrate 2, 2′. In this case, a separate multi-layer ceramic substrate 2, 2′ is provided for each heat source 1, 1′. Preferably, thermally conductive material 6a, 6a′ (solder paste or Ag sintering paste) is situated between the respective heat source 1, 1′ and the respective multi-layer ceramic substrate 2, 2′ (not explicitly illustrated).

The multi-layer ceramic substrate 2, 2′ is respectively arranged on a separate heat sink 4, 4′. Thermally conductive material 6b, 6b′ (electrically insulating thermally conductive paste) can in turn be arranged between the heat sink 4, 4′ and the multi-layer ceramic substrate 2, 2′.

The use of separate heat sinks 4, 4′ or cooling systems enables the power loss of the respective heat source 1, 1′ to be individually adapted. By way of example, the heat loss of heat sources or LED matrix modules 1, 1′ of different sizes/performance levels in the carrier system 10 can be effectively dissipated by means of individually adapted cooling systems/heat sinks 4, 4′. In this regard, the heat sink 4 assigned to the heat source 1 having a greater number of LEDs is configured to be larger than the other heat sink 4. In particular, the heat sink 4 has larger cooling ribs, as a result of which a greater cooling capacity can be achieved.

It goes without saying that a plurality of heat sources 1, 1′/LED matrix modules having an identical number of LEDs can also find application, the heat loss of which is then dissipated from the carrier system 10 by way of similarly or identically configured heat sinks 4, 4′.

The complete system composed of heat sources 1, 1′, multi-layer ceramic substrate 2, 2′ and heat sinks 4, 4′ is arranged on a common carrier 9. The carrier 9 can be, for example, a purely mechanical carrier, for example, in the form of a printed circuit board, or a further, superordinate heat sink. The carrier can comprise an aluminum casting material. The carrier 9 serves for mechanical stabilization and/or better cooling of the carrier system 10.

FIG. 9 shows a sectional illustration of a multi-layer carrier system 10 in accordance with a further exemplary embodiment. The carrier system 10 comprises a plurality of heat sources 1, 1′, 1″. In this exemplary embodiment, three heat sources are illustrated, but the carrier system 10 can also comprise two heat sources, or four heat sources or more heat sources. The respective heat source 1, 1′, 1″ comprises an LED matrix module. In this exemplary embodiment, all LED matrix modules preferably comprise the same number of LEDs.

The respective heat source 1, 1′, 1″ is arranged on a multi-layer ceramic substrate 2, 2′, 2″. In this case, a separate multi-layer ceramic substrate 2, 2′, 2″ is provided for each heat source 1, 1′, 1″. Preferably, thermally conductive material (solder paste or Ag sintering paste) is situated between the respective heat source 1, 1′, 1″ and the respective multi-layer ceramic substrate 2, 2′, 2″ (not explicitly illustrated).

The multi-layer ceramic substrate 2, 2′, 2″ is respectively arranged on a separate substrate 3, 3′, 3″, which serves firstly for redistribution wiring and secondly as a stress buffer for compensating for the different coefficients of expansion of multi-layer ceramic substrate 2 and heat sink 4. Furthermore, the substrate 3, 3′, 3″ can also have a high thermal conductivity, as has already been described in association with FIGS. 1 and 3. This applies in particular to a ceramic substrate comprising, for example, AlN or Al₂O₃.

The respective ceramic substrate 3, 3′, 3″ is arranged on a common heat sink 4. The heat sources 1, 1′, 1″ thus have a common cooling system. A common cooling system is advantageous in particular if the heat sources 1, 1′, 1″ produce a similar heat loss. Furthermore, a larger number of cooling ribs can be provided by a common cooling system, since regions between the individual LED matrix modules are covered as well. The cooling capacity can thus be increased.

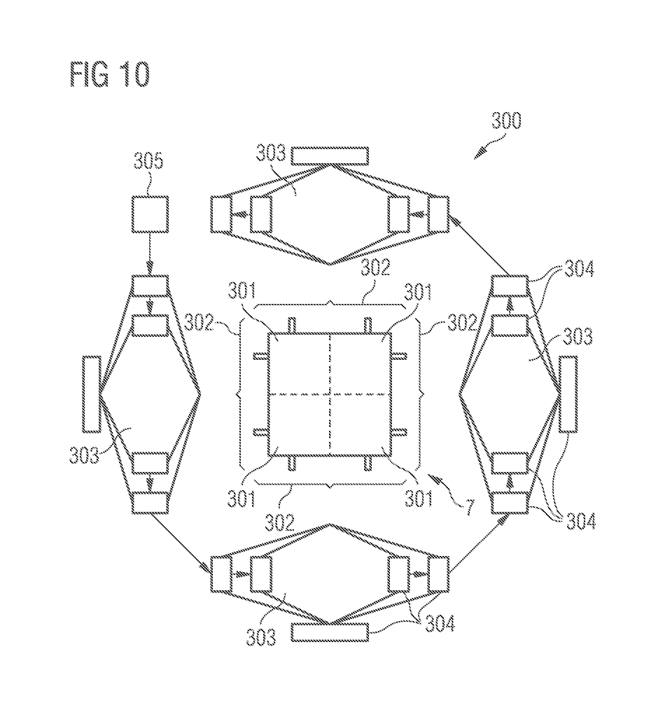

FIG. 10 shows one exemplary embodiment of a driver concept for a multi-layer carrier system.

For individual driving of a 4×8×8 LED matrix module 7 having 256 individual LEDs, the module 7 is physically divided into four quadrants 301 each having 8×8 LEDs. In this case, the left curly bracket 302 encompasses the LED region 1 to 64. The upper curly bracket 302 encompasses LEDs 65 to 128. The lower curly bracket 302 designates LEDs 129 to 192. The right curly bracket 32 designates LEDs 193 to 256.

If individual LEDs of the quadrants 301 of the module 7 are driven/switched on, then a local temperature increase occurs. In this regard, the temperature is increased from room temperature (approximately 25° C.) to approximately 70° C. to 100° C. This heat has to be dissipated uniformly. The internal wiring of the LEDs must therefore be configured such that a uniform heat dissipation and also a uniform electrical power distribution are effected. In particular, the redistribution wiring by way of the different planes must be configured uniformly.

A plurality of drivers are required—depending on the specification—for the individual driving of the 256 LEDs. In this exemplary embodiment, 32 drivers 303 are provided, wherein each driver can drive eight LEDs.

A high power is produced by the LED module 7. The drivers 303 therefore require a current supply. Overall, 25.6 A are required for 256 LEDs (approximately 100 mA per LED). Converters 304 serve to supply the individual drivers 303.

The drivers 303 are driven by way of a central microcontroller 305. The microcontroller 305 is connected to a data bus in a motor vehicle, for example. The microcontroller 305 can be connected to the CAN bus or the ETHERNET bus, for example. The data bus is in turn connected to a central control unit.

A method for producing a multi-layer carrier system 10 is described by way of example below. All features that have been described in association with the carrier system 10 also find application for the method, and vice versa.

A first step involves providing the multi-layer ceramic substrate 2. The multi-layer ceramic substrate 2 preferably corresponds to the multi-layer ceramic substrate 2 described above. The multi-layer ceramic substrate 2 preferably comprises a varistor ceramic.

Producing the varistor having a multi-layer structure involves firstly producing green ceramic sheets made from the dielectric ceramic components. The ceramic sheets in this case can comprise, for example, ZnO and various dopings.

Furthermore, the ceramic is preferably constituted such that it can already be sintered with high quality below the melting point of the material of the integrated metal structures (internal electrodes, vias, ESD structures). A liquid phase that already exists at low temperatures is therefore required during the sintering. This is ensured, for example, by a liquid phase such as bismuth oxide. The ceramic can therefore be based on zinc oxide doped with bismuth oxide.

The internal electrodes 202 are applied on the ceramic sheets by the green ceramic being coated with a metallization paste in the electrode pattern. The metallization paste comprises Ag and/or Pd, for example. The ESD structure 202 is applied on the ceramic sheets. Furthermore, perforations for forming the vias 8, 202 are introduced into the green sheets. The perforations can be produced by means of stamping or laser treatment of the green sheets. The perforations are subsequently filled with a metal (preferably Ag and/or Pd). The metallized green sheets are stacked.

The green body is subsequently pressed and sintered. The sintering temperature is adapted to the material of the internal electrodes 202. In the case of Ag internal electrodes, the sintering temperature is preferably less than 1000° C., for example, 900° C.

A partial region of the surface of the sintered green stack is subsequently metallized. By way of example, in this case Ag, Cu or Pd is printed onto the top side and the underside of the sintered green stack. After the metallized stack has been thoroughly heated, unprotected structures or regions of the stack are sealed. To that end, glass or ceramic is printed onto the underside and the top side.

An optional further step (see carrier system in accordance with FIGS. 1 and 3) involves providing the substrate 3. The substrate 3 preferably corresponds to the substrate 3 described above. The substrate 3 can comprise a ceramic (varistor ceramic, Al₂O₃, AlN) or a metal (IMS substrate, metal-core printed circuit board). Conductor tracks, for example, comprising or composed of copper, are preferably formed at a top side of the substrate 3. The multi-layer ceramic substrate 2 is arranged on the top side of the substrate 3. By way of example, in an upstream step, a solder paste or an Ag sintering paste can be applied on the top side of the substrate 3. The physical connection between the substrate 3 and the multi-layer ceramic substrate 2 is effected by means of reflow soldering. The method step just described is obviated in the case of the carrier system 10 in accordance with FIG. 2, which does not comprise a substrate 3.

An optional further step (see carrier system in accordance with FIG. 4) involves providing the printed circuit board 5. The printed circuit board 5 is arranged around the substrate 3. The substrate 3, secured to the multi-layer ceramic substrate 2, is introduced into the cutout 5a of the printed circuit board 5. Printed circuit board 5 and substrate 3 are subsequently connected to one another by way of a plug connection 26 or a bond wire 26. The method step just described is obviated in the case of the carrier systems 10 in accordance with FIGS. 1 to 3, which do not comprise a printed circuit board 5.

A next step involves arranging at least one LED matrix module 7 on the top side of the multi-layer ceramic substrate 2. By way of example, in an upstream step, a solder paste or an Ag sintering paste can be applied on the top side of the multi-layer ceramic substrate 2. By means of Ag sintering (for example, μAg sintering) or soldering, the matrix module 7 is fixedly connected to the multi-layer ceramic substrate 2. The advantage of μAg is that the silver already melts at low temperatures of 200° C. to 250° C. and does not subsequently reflow.

Driver components for the driver circuit are then made available. Depending on the embodiment of the carrier system 10, the driver components are realized on the multi-layer ceramic substrate 2, on the substrate 3 or on the printed circuit board 5. The driver circuit is connected to the multi-layer ceramic substrate 2, on the substrate 3 or on the printed circuit board 5 by reflow soldering.

By means of the driver components, the LEDs are individually driven by way of the wiring integrated into the multi-layer ceramic substrate 2. The driver circuit is electrically conductively connected to the internal electrodes 202 and the vias 8, 201.

In a last step, the heat sink 4 is provided and secured to the carrier system 10. The heat sink 4 is adhesively bonded, for example, to the multi-layer ceramic substrate 2 or to the substrate 3. The heat sink can comprise an aluminum casting material. In this case, in an upstream step, a thermally conductive paste is applied on the underside of the substrate 3 or of the multi-layer ceramic substrate 2. Afterward, the carrier system 10 is baked for solidification. In this case, temperature differences scarcely occur, with the result that thermal stresses between the individual components are avoided in this method step.

As an alternative thereto, however, the heat sink 4 can also comprise materials having a coefficient of thermal expansion similar to that of the substrate 3 and/or the multi-layer ceramic substrate 2. By way of example, the heat sink 4 can comprise aluminum-silicon carbide, copper-tungsten or copper-molybdenum. In this case, applying the thermally conductive paste 6b can also be obviated or a thinner layer of the thermally conductive paste 6b can be applied.

The carrier system 10 produced comprises at least one matrix light module having punctiform individual driving of a large number of LEDs. This enables the surroundings to be illuminated (or else the light to be dipped) with significantly greater differentiation than in the case of solutions comprising LED array segments. The construction by way of a multi-layer varistor having high thermal conductivity allows a very compact embodiment, the integration of ESD protection components and the construction of the driver circuit directly on the ceramic. A compact and highly adaptive carrier system 10 is thus produced.

The description of the subjects specified here is not restricted to the individual specific embodiments. Rather, the features of the individual embodiments can be combined—in so far as technically expedient—arbitrarily with one another.

1-20. (canceled)

21. A multi-layer carrier system comprising:
at least one multi-layer ceramic substrate; and
at least one matrix module of heat-producing semiconductor components,
wherein the semiconductor components are arranged on the multi-layer ceramic substrate, and
wherein the matrix module is electrically conductively connected to a driver circuit by way of the multi-layer ceramic substrate.

22. The multi-layer carrier system according to claim 21, wherein the at least one matrix module comprises an LED matrix module including a plurality of individual LEDs and/or LED arrays.

23. The multi-layer carrier system according to claim 21, wherein the multi-layer carrier system is configured to individually drive the semiconductor components of the matrix module.

24. The multi-layer carrier system according to claim 21, wherein the multi-layer ceramic substrate comprises an integrated multi-layer wiring for individually driving the semiconductor components.

25. The multi-layer carrier system according to claim 21, wherein the multi-layer ceramic substrate comprises a varistor ceramic.

26. The multi-layer carrier system according to claim 25, wherein the multi-layer ceramic substrate comprises a plurality of internal electrodes and vias, and wherein the internal electrodes are arranged between varistor layers of the multi-layer ceramic substrate and are electrically conductively connected to the vias.

27. The multi-layer carrier system according to claim 21, wherein the multi-layer ceramic substrate comprises an integrated ESD structure.

28. The multi-layer carrier system according to claim 21, wherein the driver circuit is constructed directly on a surface of the multi-layer ceramic substrate.

29. The multi-layer carrier system according to claim 21, wherein the multi-layer ceramic substrate has an integrated temperature sensor or an over-temperature protective function.

30. The multi-layer carrier system according to claim 21, further comprising a further substrate, wherein the multi-layer ceramic substrate is arranged on the further substrate, and wherein the driver circuit is constructed directly on a surface of the further substrate.

31. The multi-layer carrier system according to claim 30, wherein the further substrate comprises AlN or AlOₓ, or an IMS substrate, a metal-core printed circuit board or a further multi-layer ceramic substrate.

32. The multi-layer carrier system according to claim 21, further comprising a further substrate and a printed circuit board, wherein the printed circuit board at least partly surrounds the further substrate, and wherein the driver circuit is constructed directly on a surface of the printed circuit board.

33. The multi-layer carrier system according to claim 32, wherein the further substrate comprises AlN or AlOx, or an IMS substrate, a metal-core printed circuit board or a further multi-layer ceramic substrate.

34. The multi-layer carrier system according to claim 21, wherein the at least one matrix module comprises at least four light modules each having m×n semiconductor components, wherein m≥2 and n≥2.

35. The multi-layer carrier system according to claim 21, further comprising a heat sink, wherein the heat sink is thermally connected to the multi-layer ceramic substrate.

36. The multi-layer carrier system according to claim 21, further comprising:
at least one additional multi-layer ceramic substrate;
at least one additional matrix module of heat-producing semiconductor components; and
at least two heat sinks,
wherein a dedicated multilayer ceramic substrate and a heat sink is provided for every matrix module,
wherein the semiconductor components are arranged on the multi-layer ceramic substrate, the heat sink is arranged on the multi-layer ceramic substrate facing opposite to the matrix module, and
wherein every matrix module is electrically conductively connected to a driver circuit by way of the multi-layer ceramic substrate.

37. A multi-layer carrier system comprising:
at least one multi-layer ceramic substrate;
at least one matrix module of heat-producing semiconductor components;
at least a further substrate comprising AlN, AlOx, an IMS substrate, a metal-core printed circuit board, or a further multi-layer ceramic substrate; and
at least one heat sink comprising aluminum-silicon carbide, copper-tungsten or copper-molybdenum,
wherein the semiconductor components are arranged on the multi-layer ceramic substrate,
wherein the multi-layer ceramic substrate is arranged on the further substrate,
wherein the further substrate is thermally connected to the heat sink, and
wherein the matrix module is electrically conductively connected to a driver circuit by way of the multi-layer ceramic substrate and the further substrate.

38. A method for producing a multi-layer carrier system, the method comprising:
producing a multi-layer ceramic substrate having integrated conductor tracks, ESD structures and vias;
providing a substrate and arranging the multi-layer ceramic substrate on the substrate;
arranging at least one matrix module of heat-producing semiconductor components at a top side of the multi-layer ceramic substrate;
connecting the arrangement comprising multi-layer ceramic substrate, matrix module and substrate by soldering or Ag sintering;
providing driver components for driving the semiconductor components by way of the conductor tracks and vias; and
thermally connecting the substrate to a heat sink.

39. The method according to claim 38, wherein the driver components are arranged on the substrate.

40. The method according to claim 38, further comprising providing a printed circuit board, wherein the printed circuit board has a cutout that completely penetrates through the printed circuit board, and wherein the substrate is introduced into the cutout and electrically conductively connected to the printed circuit board.

41. The method according to claim 40, wherein the driver components are arranged on the printed circuit board.

42. The method according to claim 38, wherein green sheets are provided for producing the multi-layer ceramic substrate, wherein the green sheets are printed with electrode structures for forming the conductor tracks, and wherein the green sheets are provided with cutouts for forming the vias.

43. An automotive LED headlight comprising the multi-layer carrier system according to claim 21.
